(19) United States
(12) Patent Application Publication
(10) Pub. No.: US 2025/0246499 A1
(43) Pub. Date: Jul. 31, 2025

(54) CHIPLET INTEGRATION STRUCTURE FOR THERMAL MANAGEMENT

(71) Applicant: INTERNATIONAL BUSINESS MACHINES CORPORATION, Armonk, NY (US)

(72) Inventors: John Knickerbocker, Monroe, NY (US); Mukta Ghate Farooq, HOPEWELL JCT, NY (US); Keiji Matsumoto, Yokohama-shi (JP)

(21) Appl. No.: 18/423,619

(22) Filed: Jan. 26, 2024

(51) Int. Cl. H01L 23/367; H01L 23/00; H01L 23/373; H01L 23/498; H01L 25/065

(52) U.S. Cl. CPC H01L 23/3672; H01L 23/3735; H01L 23/49822; H01L 24/08; H01L 24/16; H01L 25/0652; H01L 2224/08146; H01L 2224/08155; H01L 2224/16055; H01L 2224/16157; H01L 2924/1434; H01L 2924/1611; H01L 2924/351

(57) ABSTRACT

An electrical device that includes a stacked semiconductor device structure connected to a device substrate through a sidewall interconnect. The sidewall interconnect of the stacked semiconductor device structure is in contact with metal lines extending from a sidewall of the stacked semiconductor device structure to semiconductor devices positioned within an interior the stacked semiconductor device structure. The electrical device includes a heat spreader connected to the stacked semiconductor structure.

### BACKGROUND

The methods and structures described herein relate generally to semiconductor device packaging, and more particularly to a thermal management of semiconductor devices.

Integrated circuits (“ICs”) are incorporated into many electronic devices. Integrated circuit (IC) packaging allows for multiple integrated circuits (ICs) to be vertically stacked in “three-dimensional (3D)” packages in order to save horizontal area on printed circuit boards (PCBs). An alternative packaging technique, referred to as 2.5D packaging, can use an interposer, which may be formed from a semiconductor material such as silicon, for coupling one or more semiconductor die to a printed circuit board (PCB). A plurality of integrated circuits (ICs) or other semiconductor dies, which may be heterogeneous technologies, may be mounted on the interposer.

One consideration of semiconductor device packaging is thermal management. As the semiconductor devices are operating, heat is generated. Different thermal characteristics of multiple structures and their different materials can result in dimensional changes and performance variations when subjected to temperature changes.

### SUMMARY

The embodiments of the present invention provide an electrical device that includes a stacked semiconductor device structure connected to a device substrate through a sidewall interconnect. The sidewall interconnect is in contact with metal lines extending from a sidewall of the stacked semiconductor device structure to semiconductor devices positioned within an interior the stacked semiconductor device structure. The electrical device includes a heat spreader connected to the stacked semiconductor structure.

In another embodiment, an electrical device is provided that includes a stacked semiconductor device structure connected to a device substrate through a sidewall interconnect for the stacked semiconductor device structure. The electrical device can also include a heat spreader present on the stacked semiconductor device structure. The electrical device also includes pillars connecting the heat spreader to the device substrate. The pillars can deform along a dimension separating the heat spreader from the device substrate.

In yet another embodiment, an electrical device is provided that includes a stacked semiconductor device structure connected to a device substrate through a sidewall interconnect for the stacked semiconductor device structure. The electrical device further includes a heat spreader connected to the stacked semiconductor device structure. In some embodiments, the heat spreader is in contact with the stacked semiconductor device structure through a deformable joint.

### BRIEF DESCRIPTION OF DRAWINGS

The disclosure will provide details in the following description of preferred embodiments with reference to the following figures wherein:

FIG. 1 is a side cross-sectional view of an electrical device that includes a stacked semiconductor device structure connected to a device substrate, and a heat spreader connected to the stacked semiconductor device structure, wherein the heat spreader is engaged to the device substrate though deformable pillars, in accordance with an embodiment of the present invention;

FIG. 2 is a top down view of the electrical device depicted in FIG. 1 illustrating the heat spreader contacting the stacked semiconductor device structure through a thermal interface material (TIM) layer, in accordance with an embodiment of the present invention;

FIG. 3 is a side cross-sectional view of the electrical device depicted in FIG. 1 including a cap layer for the heat spreader atop the stacked semiconductor device structure, in accordance with an embodiment of the present invention;

FIG. 4 is a top down view of the electrical device depicted in FIG. 3 illustrating vent openings in the cap layer for the heat spreader, in accordance with an embodiment of the present invention;

FIG. 5 is a side cross-sectional view illustrating a thermally conductive compliant pad on exterior surfaces of the stacked semiconductor device structure, in accordance with an embodiment of the present invention;

FIG. 6 is a side cross-sectional view of another embodiment of the electrical device that includes a stacked semiconductor device structure and a heat spreader that is in engagement to the stacked semiconductor device structure through a deformable joint, in accordance with an embodiment of the present invention;

FIG. 7 is a top down view of the electrical device depicted in FIG. 6 depicting a deformable joint on each side of the stacked semiconductor device structure connecting the stacked semiconductor device structure to the heat spreader, in accordance with an embodiment of the present invention;

FIG. 8 is a side cross-sectional view of the electrical device depicted in FIG. 6 including a notched cap for the heat spreader atop the stacked semiconductor device structure, in accordance with an embodiment of the present invention;

FIG. 9 is a side cross-sectional view depicting deformable joints including pistons with a sidewall including fin protrusions positioned between the stacked semiconductor device and the heat spreader, in accordance with an embodiment of the present invention;

FIG. 10 is a side cross-sectional view of an embodiment of the electrical device including a heat spreader having fluid channels for liquid coolant, in accordance with an embodiment of the present invention;

FIG. 11 is a side cross-sectional view of an electrical device including a laminate to increase the stiffness of the device substrate, in accordance with an embodiment of the present invention;

FIG. 12 is a bottom view illustrating forming a backside redistribution layer (RDL) on a semiconductor wafer processed to provide semiconductor devices, in accordance with an embodiment of the present invention;

FIG. 13 is a side cross-sectional view illustrating dicing of the semiconductor wafer into individual semiconductor chips and stacking the chips to provide the stacked semiconductor devices structure, in accordance with an embodiment of the present invention;

FIG. 14 is a side cross-sectional view illustrating rotating the stacked semiconductor device structure 90 degrees from its position depicted in FIG. 13, and planarizing a sidewall of the stacked semiconductor device structure, in accordance with an embodiment of the present invention;

FIG. 15 is a bottom view depicting forming a sidewall redistribution layer on the planarized sidewall of the stacked semiconductor device structure, in accordance with an embodiment of the present invention;

FIG. 16 is a bottom view depicting forming metal contacts for the sidewall interconnects on contact portions of the sidewall redistribution layer, in accordance with an embodiment of the present invention;

FIG. 17 is a side cross-sectional view depicting engaging the stacked semiconductor device structure to the first socket of the device substrate and forming a thermal interface material layer on the stacked semiconductor device structure, in accordance with an embodiment of the present invention;

FIG. 18 is a side cross-sectional view of connecting the first side component and the second side components of the heat spreader to the stacked semiconductor device structure, in accordance with an embodiment of the present invention; and

FIG. 19 is a side cross-sectional view of connecting the cap layer to the heat spreader, in accordance with an embodiment of the present invention.

### DETAILED DESCRIPTION OF PREFERRED EMBODIMENTS

In accordance with embodiments of the present invention, devices and methods are described herein that can provide thermal management for stacked semiconductor device structures, such as, e.g., chiplets. It has been determined that it can be difficult to effectively cool a center of stacked semiconductor device structures. A stacked semiconductor device structure, e.g., three dimensional integrated circuit (3DIC), can be built by vertically stacking different chips or wafers together into a single package. Within the package, the elements of the device can be interconnected using through-silicon vias (TSVs) or hybrid bonding.

Thermal management of stacked semiconductor device structures is generally provided by top side thermal management. Top side thermal management has been determined to be insufficient to cool stacked semiconductor device structures, because it can be difficult for the heat that is generated in the lower and middle levels of the stack structure to be transmitted to the upper surface of the stack to be dissipated from the structure. In some examples, the heat that is generated in the lower and middle levels of the stacked structure can be generated in the middle and lower layers of a stacked chiplet, or generated in the backside power distribution layers (BSPDN).

The structures and methods of some embodiments of the present invention can overcome these disadvantages by positioning a sidewall interconnect onto a sidewall of the stacked semiconductor device structure, rotating the stacked semiconductor device structure, e.g., by 90 degrees, and then connecting the stacked semiconductor device structure onto the device substrate through the sidewall interconnect. The sidewall interconnect is in thermal communication with metal lines that extend from the sidewall of the stacked semiconductor device structure to the heat producing elements, such as semiconductor devices, within an interior of the stacked semiconductor device structure. The metal lines provide a thermal pathway from the heat producing elements within the interior of the stacked semiconductor device structure through the sidewall interconnect to the device substrate. The device substrate can function to dissipate the heat generated by the stacked semiconductor device structure. Further, a thermal spreader is engaged to the faces of the stacked semiconductor device structure that are not engaged to the sidewall interconnect. Heat generated within the stacked semiconductor device structure can be cooled through both the heat spreader that is connected to the stacked semiconductor device structure, and the engagement of the sidewall interconnect for the stacked semiconductor device structure to the device substrate.

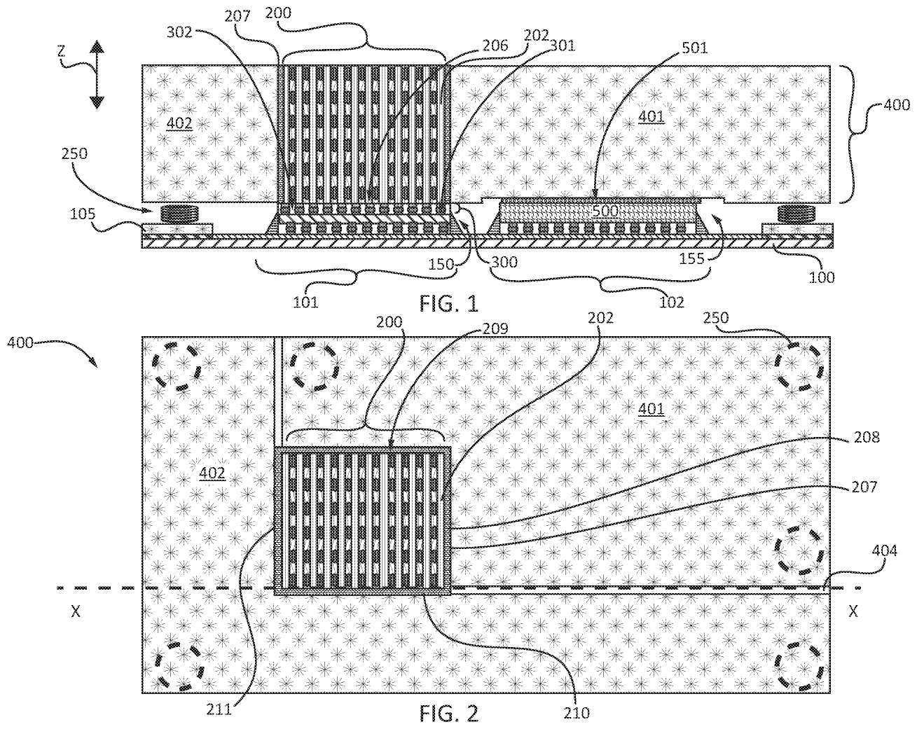

Referring now to the drawings in which like numerals represent the same or similar elements and initially to FIG. 1, devices and methods for manufacturing a semiconductor device are shown in accordance with embodiments of the present invention.

FIG. 1 illustrates an embodiment of a stacked semiconductor device structure 200 connected to a device substrate 100. The stacked semiconductor device structure 200 may include semiconductor chip levels 202 that are vertically stacked. Each of the semiconductor chip levels 202 can include a semiconductor substrate and at least one semiconductor device, as well as interconnect structures and dielectric layers. The semiconductor devices may include field effect transistors (FETs), fin field effect transistors (FinFETs), nanosheet channel semiconductor devices, vertical field effect transistors (VFETs). The semiconductor devices 204 can also include memory chips, such as static random-access memory (static RAM or SRAM), dynamic random-access memory (DRAM), ferroelectric random access memory (FRAM), resistive processing unit (RPU) memory and combinations thereof.

The stacked semiconductor device structure 200 may be a chiplet. A “chiplet” is an integrated circuit (IC) that contains a subset of functionality. In some embodiments, chiplets are designed to be combined with an interposer in a single package.

The device substrate 100 that the stacked semiconductor device structure 200 is connected to may include an interposer structure. In some examples, the interposer structure can be a structure that provides electrical interface routing between one socket or connection to another socket or connection. For example, in the embodiments depicted in FIG. 1, the device substrate 100 includes a first socket 150 for engagement by the stacked semiconductor device structure 200, and a second socket 155 for engagement by a processing unit 500, such as a graphic processing unit (GPU) or a computing processing unit (CPU). The first socket 150 can provide for engagement of the stacked semiconductor device structure 200 to a first region 101 of the device substrate 100, and the second socket 155 can provide for engagement of the processing unit 500 to a second region 102 of the device substrate 100. It is noted that this is only one example of how devices may be connected to the device substrate 100. For example, more than one stacked semiconductor device structure 200 may be connected to the device substrate 100, and more than one of the processing unit 500 may be connected to the device substrate 100.

The processing unit 500 and the stacked semiconductor device structure 200 may be in electrical communication across the device substrate 100. The purpose of an interposer can be to spread a connection to a wider pitch or to reroute a connection to a different connection. In some embodiments, the device substrate 100 may have a semiconductor material composition, such as silicon. In some embodiments, when the device substrate 100 is an interposer, the device substrate 100 may have a glass composition. In some embodiments, when the device substrate 100 is an interposer, the device substrate 100 may have an organic composition. It is noted that the device substrate 100 is not limited to being an interposer structure as described above, as other embodiments have also been contemplated.

Referring to FIG. 1, the stacked semiconductor device structure 200 may be connected to the device substrate 100 through a planarized sidewall 206 that engages the first socket 150 of the device substrate 100. In some embodiments, the planarized sidewall 206 includes the connection points to a redistribution layer (RDL) layer, which provides electrical lines, e.g., metal lines, to the semiconductor devices that are present in the semiconductor chip levels 202. The connection points for the redistribution layer (RDL) layer are contacted by a sidewall interconnect 300. The sidewall interconnect 300 includes metal contacts 301 for transmission of electrical signal via current from the stacked semiconductor device structure 200 to the device substrate 100. The metal contacts 301 provide for engagement of the stacked semiconductor device structure 200 to the first socket 150 on the device substrate 100. A dielectric fill 302 is present between the metal contacts 301 of the sidewall interconnect 300. The dielectric fill 302 provides for electrical isolation between the metal contacts 301, and can also provide for mechanical reinforcement of the metal contacts 301.

Referring to FIG. 1, the stacked semiconductor device structure 200 may be connected to the first socket 150 of device substrate 100 through the sidewall interconnect 300. In comparison to stacked semiconductor device structures that employ contacts formed along their base surfaces for connection to supporting substrates and interposers, the stacked semiconductor device structure 200 that is depicted in FIG. 1 is rotated approximately 90 degrees to align the planarized sidewall 206 of the stacked semiconductor device structure 200 to the first socket 150 of the device substrate 100. Once the stacked semiconductor device structure 200 is engaged to the first socket 150 of the device substrate 100, the sidewall interconnect 300 provides both electrical pathways and thermally conductive pathways from the stacked semiconductor device structure 200 to the device substrate 100. The thermally conductive pathway through the sidewall of the stacked semiconductor device structure 200 provides a direct pathway to cool the center of the stacked semiconductor device structure 200 to avoid thermal gradients resulting from the buildup of heat in the center of the stacked semiconductor device structure 200. For example, the sidewall interconnect 300 is in contact with metal lines extending from the planarized sidewall 206 of the stacked semiconductor device structure 200 to semiconductor devices positioned within an interior the stacked semiconductor device structure 200.

Still referring to FIG. 1, with one sidewall of the stacked semiconductor device structure 200 connected to the device substrate 100 provided by the planarized sidewall 206, the base and upper surfaces of the stacked semiconductor device structure 200 are positioned to be contacted by a heat spreader 400. In some embodiments, the heat spreader 400 is a thermal packaging component that can dissipate the heat generated by the stacked semiconductor device structure 200. In some embodiments, the heat spreader 400 has a molybdenum copper (MoCu) composition. In some embodiments, the heat spreader 400 has a copper molybdenum copper (CMC) laminate composition. In one example, the copper molybdenum copper (CMC) laminate is a three-layered structure. The copper molybdenum copper (CMC) laminate can include two outer copper layers and one molybdenum core layer. In some embodiments, the heat spreader 400 may be a Copper Molybdenum-Copper Copper (CPC) Heat Spreader. A Copper Molybdenum-Copper Copper (CPC) heat spreader includes two copper outer layers and a core having an alloyed composition of molybdenum and copper, in which the wt. % of copper ranges from 15% to 40%. In yet another example, the heat spreader 400 may be five layers of molybdenum and copper laminate. In yet an even further example, the heat spreader 400 can be composed of a tungsten copper (WCu) alloy. The fractions of tungsten and copper for the heat spreader 400 may range from W90Cu10 to W60Cu40. In some embodiments, the heat spreader 400 may have a copper diamond (CuC) composition.

The heat spreader 400 may contact the stacked semiconductor device structure 200 through a thermal interface material (TIM) layer 207. The thermal interface material (TIM) layer 207 may be present on the sidewalls of the stacked semiconductor device structure 200 that are not directed connected to the first socket 150 of the device substrate 100. The thermal interface material (TIM) layer 207 may also be present on the upper surface of the stacked semiconductor device structure 200. In some embodiments, the thermal interface material (TIM) layer 207 may include a paste or composite material that includes a dispersed phase of thermally conductive filler, particles, filaments, or ribbons. The dispersed phase have a metal composition selected from Ag, Al, Ni, In, Sn, Cu or combinations thereof. The dispersed phase may have an inorganic material composition selected from AlN, SiN, SiC, diamond, or carbon. In some other examples, the thermal interface (TIM) layer 207 may also be a compliant film, organic material, adhesive, silicone, epoxy, or combination thereof.

In some embodiments, the heat spreader 400 can be a multi-component structure. For example, a first side component 401 of the heat spreader 400 may be in direct contact with a first portion the stacked semiconductor device structure 200 and the processing unit 500, e.g., central processing unit (CPU) or graphic processing unit (GPU). The upper surface of the processing unit 500 may be in contact with a bottom surface of the first side component 401 of the heat spreader 400 through a processing unit interface layer 501 that can be a thermal interface material (TIM), a thermal adhesive or a thermal grease. A second side component 402 of the heat spreader 400 may be in direct contact with a second portion of the stacked semiconductor device structure 200. The combination of the first side component 401 and the second side component 402 of the heat spreader 400 can contact each side of the stacked semiconductor device structure 200 engaged to the first socket 150. The heat spreader 400 provides another mechanism for dissipating heat generated within the stacked semiconductor device structure 200.

Still referring to FIG. 1, in some embodiments, the heat spreader 400 is engaged to the device substrate 100 by pillars 250. In some embodiments, the pillars 250 can deform along a dimension (e.g., along the z-axis) separating the heat spreader 400 from the device substrate 100. The heat spreader 400 can deform from changes in temperature it is exposed to while dissipating heat from the stacked semiconductor device structure 200. In some instances, the thermal expansion characteristics of the heat spreader 400 can be sufficiently different from the thermal expansion characteristics of the surrounding structures, such as the device substrate 100. For example, the thermal expansion characteristics (e.g., coefficient of thermal expansion (TEC)) of the heat spreader 400 can be greater than the thermal expansion characteristics of the device substrate 100, which could cause the heat spreader 400 to warp or deform more severely than the device substrate 100. For example, if the heat spreader 400 is engaged in a fixed relationship with the device substrate 100, the deformation of the heat spreader 400 could be severe enough to impact the engagement of the stacked semiconductor device structure 200 to the first socket 150, or impact the engagement of the processing unit to the second socket 155. More specifically, in some instances, severe deformation of the heat spreader 400, which is connected to stacked semiconductor device structure 200, can cause the stacked semiconductor device structure 200 to be disengaged from the first socket 150. This mechanism by which electrical components can be dislodged from their connections due to thermal expansion of surrounding materials can be referred to as thermo-mechanical stress induced dislocation.

In some embodiments, to mitigate deformation of the heat spreader 400, the pillars 250 can deform along the dimension (along the Z-axis) separating the heat spreader 400 from the device substrate 100. In some embodiments, the pillars 250 may include springs. The springs for the pillars 250 can be coil spring, leaf springs, spiral springs, Z-shaped spring, V-shaped springs, stacked Z or stacked V shaped springs or a combination thereof. In some embodiments, the pillars 250 can also be provided by a compliant column structure. The compliant column structure can include a matrix of thermally conductive pillars, fibers, and/or ribbons in a compliant matrix of silicone, rubber or polymer. In some examples, the matrix material, e.g., being polymeric, allows for deformation to mitigate thermo-mechanical stress induced dislocation of the stacked semiconductor device structure 200 from the first socket 150. The ribbons that can be integrated within the compliant column can be provided by sheet metal that is formed into a Z-shape cross-section, or by sheet metal having a cross-section of a plurality of V-shaped grooves.

In some examples, when the heat spreader 400 experiences thermally induced changes in geometry, the pillars 250 can deform to accommodate the changes in the geometry in the heat spreader 400 without inducing mechanical stresses to the electrical connections of the stacked semiconductor device structure 200 to the device substrate 100. Deformation of the pillars 250 relieves the mechanical stress from being transmitted from the heat spreader 400 to the device substrate 100, which eliminates stress at the connection point between the first socket 150 of the device substrate 100 and the sidewall interconnect 300 of the stacked semiconductor device structure 200.

In some embodiments, the pillars 250 can also provide a thermal pathway through which heat can be dissipated from the heat spreader 400 to the device substrate 100. The pillars 250 include a thermally conductive material composition. Further, the connection points of the pillars 250 to the device substrate 100 and the heat spreader 400 also include a thermally conductive material. For example, the pillars 250 may be engaged to the device substrate 100 by a seal band 105. In some embodiments, the seal band 105 is provided by a conductive pad. The conductive pad can include a conductive material, such as silver, gold, copper, aluminum or a combination thereof. The seal band 105 may provide a site for solder connections of the pillars 250 to the device substrate 100. Solder connections may also be used to connect the pillars 250 to the heat spreader 400.

FIG. 2 is a top down view of the structure depicted in FIG. 1 illustrating sidewall bodies, e.g., first side component 401 and second side component 402, of the heat spreader 400 contacting the stacked semiconductor device structure 200, in accordance with an embodiment of the present invention. The cross-section depicted in FIG. 1 is along section line X-X of FIG. 2. The stacked semiconductor device structure 200 is depicted having four sides, in which the thermal interface layer (TIM) layer 207 is present on each side of the stacked semiconductor device structure 200. The first side component 401 of the heat spreader 400 contacts a first side 208 and second side 209 of the stacked semiconductor device structure 200 through a portion of the thermal interface material (TIM) layer 207. The second side component 402 of the heat spreader 400 contacts the remaining third side 210 and fourth side 211 the stacked semiconductor device structure 200 through another portion of the thermal interface material (TIM) layer 207. The combinations of the first side component 401 and second side component 402 of the heat spreader 400 entirely surround the stacked semiconductor device structure 200. More particularly, each face of the stacked semiconductor device structure 200 that is not directly engaged to the device substrate 100 may be in contact with the heat spreader 400. Further, the interfaces of the first side component 401 and the second side component 402 of the heat spreader 400 may be filled with thermal conductive adhesive 404. The pillars 250 that are present underlying the heat spreader 400 are depicted in FIG. 2 with broken lines.

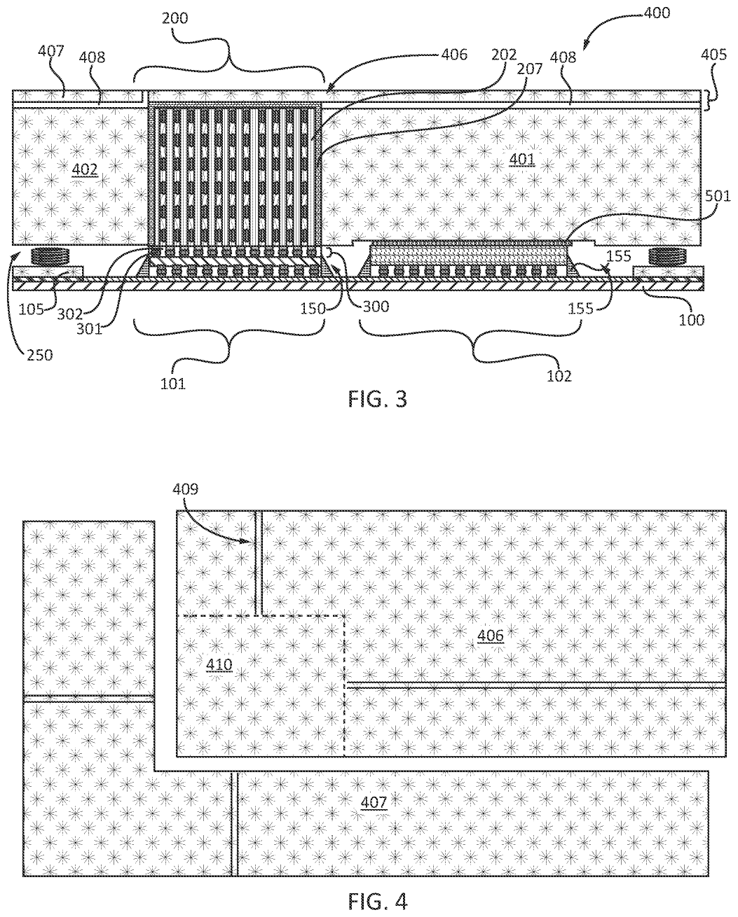

FIG. 3 is a side cross-sectional view of an embodiment of the semiconductor device depicting a cap layer 405 for the heat spreader 400 atop the stacked semiconductor device structure 200. The cap layer 405 may be composed of a thermally conductive material. In some embodiments, any of the thermally conductive materials for the heat spreader 400 may be employed in the cap layer 405. The cap layer 405 may be a multi-component structure. For example, the cap layer 405 may include a first cap component 406 and a second cap component 407. In an embodiment, the first cap component 406 of the cap layer 405 is present overlying the first side component 401 of the heat spreader 400. In some embodiments, the first cap component 406 is in direct contact with a cap thermal interface material (TIM) layer 408. The cap thermal interface material (TIM) layer 408 provides a thermal interface between the first cap component 406 and the first side component 401 of the heat spreader 400, as well as the stacked semiconductor device structure 200. The second cap component 407 is present overlying the second side component 402 of the heat spreader 400. The second cap component 407 is also in direct contact with the cap thermal interface (TIM) layer 408. The cap thermal interface material (TIM) layer 408 provides a thermal interface between the second cap component 407 and the second side component 402 of the heat spreader 400. A portion of the cap thermal interface material (TIM) layer 408 is also present between the first cap component 406 and the second cap component 407 of the cap layer 405. In the embodiment depicted in FIG. 3, the stacked semiconductor device structure 200 is entirely encased by the heat spreader 400. It is noted that is some embodiments, the cap layer 405 of the heat spreader 400 may be omitted.

FIG. 4 is a top down view of the structure depicted in FIG. 3 illustrating the upper surface of the cap layer 405 which includes vent openings 409 that are formed therein. The broken lines illustrate a cap over stacked semiconductor portion 410 of the first cap component 406 of the cap layer 405 for the heat spreader 400. The cap over stacked semiconductor portion 410 is present over the stacked semiconductor device structure 200. In some embodiments, a portion of the vent openings 409 extend from the cap over stacked semiconductor portion 410 of the first cap component 406 of the heat spreader 400. Another portion of the vent openings 409 are present in the second cap component 407 of the cap layer 405. In some embodiments, the vent openings 409 are semi-circular shaped recesses formed in the upper surface of the first cap component 406 and the second cap component 407 of the cap layer 405. The vent openings 409 provide another mechanism by which heat may be dissipated for cooling the stacked semiconductor device structure 200.

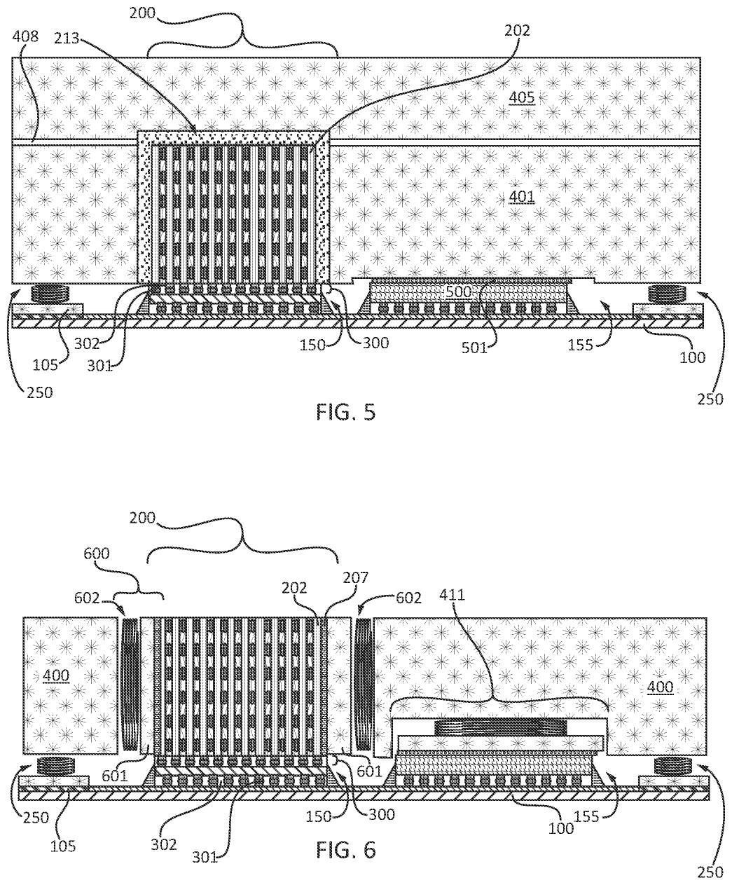

FIG. 5 is a side cross-sectional view of an embodiment of electrical device that includes a thermally conductive polymeric pad 213 on the exterior surfaces of the stacked semiconductor device structure 200. The thermally conductive polymeric pad 213 may be positioned between the stacked semiconductor device structure 200 and the heat spreader 400. The thermally conductive polymeric pad 213 can provide a thermal pathway for the dissipation of heat from the stacked semiconductor device structure 200 to the heat spreader 400. The thermally conductive polymeric pad 213 can have a silicone composition. In some embodiments, the thermally conductive polymeric pad 213 may be substituted for the thermal interface material (TIM) layer 207. The thermally conductive polymeric pad 213 may be a compliant structure. The compliant characteristic of the thermally conductive polymeric pad 213 at the interface of the stacked semiconductor device structure 200 and the heat spreader 400 can deform to avoid thermo-mechanical stresses that result from temperature changes in the heat spreader 400 impacting the stacked semiconductor device structure 200.

FIG. 6 is a side cross-sectional view of another embodiment of an electrical device that includes a stacked semiconductor device structure 200, and a heat spreader 400, in which deformable joints 600 are present at the interfaces between the stacked semiconductor device structure 200 and the heat spreader 400. The electrical device depicted in FIG. 6 is similar to the electrical device depicted in FIGS. 1-4, with the exception that the electrical device depicted in FIG. 6 includes the further element of the deformable joints 600. For example, the stacked semiconductor device structure 200 depicted in FIG. 6 is engaged to the device substrate 100 through a sidewall interconnect 300. Further, the device substrate 100 and the heat spreader 400 depicted in FIG. 6 are connected through pillars 250 that can deform along the dimension (e.g., along the Z-axis) separating the heat spreader 400 from the device substrate 100. The ability of the pillars 250 that are connecting the device substrate 100 and the heat spreader 400 to deform can relieve thermo-mechanical stresses that result from temperature changes in the electrical device.

Referring to FIG. 6, the deformable joints 600 positioned between the stacked semiconductor device structure 200 and the heat spreader 400 are another mechanism by which stresses resulting from temperature change induced dimensional changes in the heat spreader 400 can be mitigated from impacting the stacked semiconductor device structure 200. In some examples, a deformable joint 600 may also be present between the heat spreader 400 and the processing unit 500.

In some embodiments, the deformable joints 600 include a piston 601 and a compliant thermal connector 602. For example, the piston 601 includes a thermally conductive material, and can is in contact with a heat producing electrical component, such as the stacked semiconductor device structure 200 or the processing unit 500. For example, the piston 601 may be in direct contact with a portion of the thermal interface material (TIM) layer 207 that is in direct contact with the stacked semiconductor device structure 200. In another example, the piston 601 may be in direct contact with the processing unit interface layer 501 that is present on the upper surface of the processing unit 500. In some examples, the piston 601 may include a metal, such as copper or aluminum. In some embodiments, the sidewalls of the piston 601 may be planar.

In some embodiments, the compliant thermal connector 602 of the deformable joints 600 may be provided by springs. For example, the springs that can provide the compliant thermal connector 602 can include coil springs, leaf springs, spiral springs, Z-shaped spring, V-shaped springs, stacked Z or stacked V shaped compliant structures or a combination thereof. In some embodiments, the compliant thermal connector 602 can also be provided by a column structure including a matrix of thermally conductive pillars, fibers, and/or ribbons in a compliant matrix of silicone, rubber, or polymer. A ribbon can be provided by sheet metal that is formed into a Z-shape cross-section, or by sheet metal having a cross section of a plurality of V-shaped grooves. The compliant thermal connector 602 may be connected to each of the piston 601 and the heat spreader 400 by solder or adhesive engagement.

FIG. 6 depicts deformable joints 600 between the stacked semiconductor device structure 200 and the heat spreader 400. A deformable joint 600 can also be present between the heat spreader 400 and the processing unit 500. In the embodiment, depicted in FIG. 6, an opening 411 may be positioned in the base surface of the heat spreader 400. The opening 411 houses the deformable joint 600 that is used for engaging the processing unit 500 to the heat spreader 400. The opening 411 provides clearance that allows for the deformable joint 600 to be positioned between the heat spreader 400 and the processing unit 500 without impacting engagement of the stacked semiconductor device structure 200 to the first socket 150.

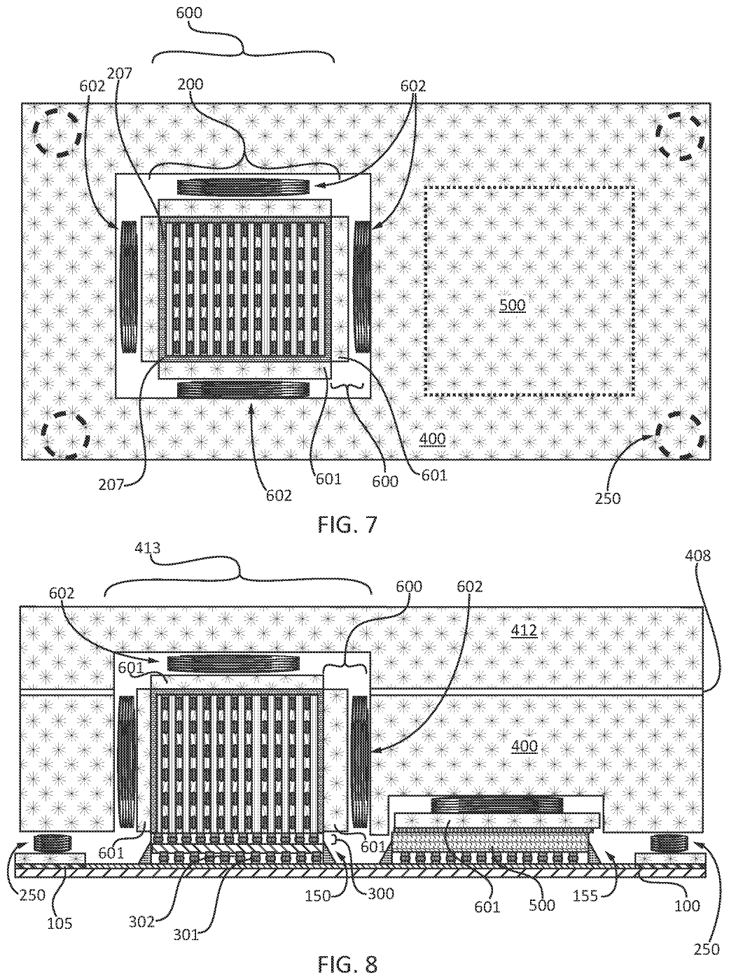

FIG. 7 is a top down view of the semiconductor device structure depicted in FIG. 6 depicting a deformable joint 600 between the stacked semiconductor device structure 200 and the heat spreader 400 on each side of the stacked semiconductor device structure 200. The broken lines illustrated in FIG. 7 depict the pillars 250 and the processing unit 500 that are under the heat spreader 400.

FIG. 8 is a side cross-sectional view of the electrical device depicted in FIG. 7 further including a notched cap 412 atop the stacked semiconductor device structure 200. The notched cap 412 in combination with the heat spreader 400 surrounds the stacked semiconductor device structure 200. The notched cap 412 has an opening 413 in its base surface that is sized to accommodate the deformable joint 600 that is connected to an upper surface of the stacked semiconductor device structure 200. The notched cap 412 may be composed of a thermally conductive material. In some embodiments, any of the thermally conductive materials for the heat spreader 400 may be employed in the notched cap 412. In some embodiments, the notched cap 412 is in direct contact with a cap thermal interface material (TIM) layer 408. The cap thermal interface material (TIM) layer 408 provides a thermal interface between the notched cap 412 and the heat spreader 400. It is noted that is some embodiments, the notched cap 412 and the deformable joint to the upper surface of the stacked semiconductor device structure 200 may be omitted.

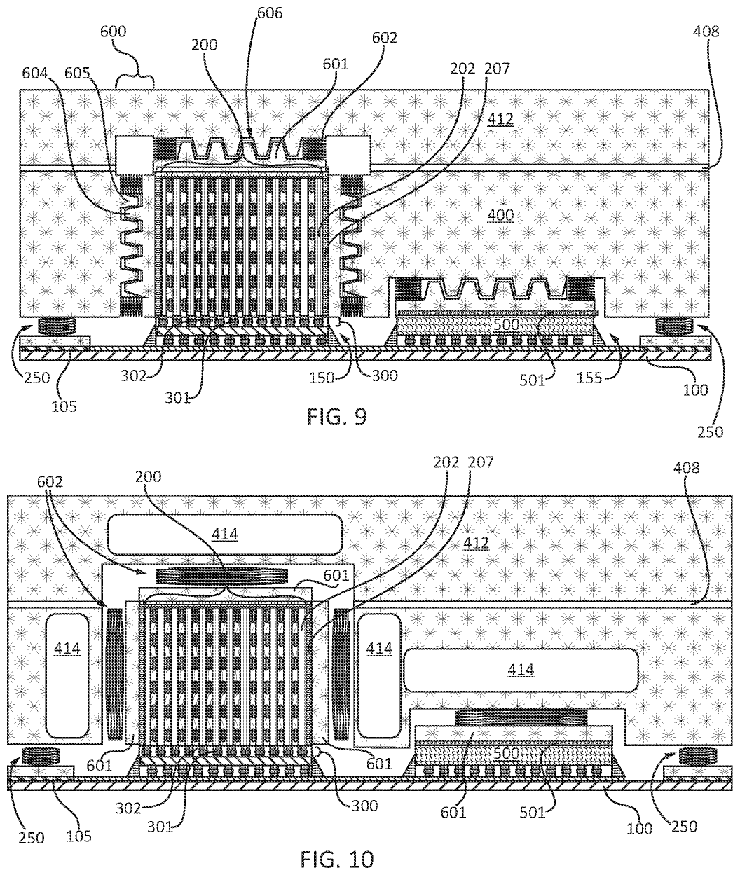

FIG. 9 is a side cross-sectional view depicting another embodiment of the present invention, in which the deformable joints 600 include compliant thermal connectors 602 and pistons 601 having fin protrusions 604. The fin protrusions 604 enhance the heat exchange performance of the pistons 601. The fin protrusions 604 may be machined and/or etched into the sidewall of the pistons 601, and can have a thermally conductive material composition. For example, the fin protrusions 604 may have an aluminum or copper containing composition.

The fin protrusions 604 of the pistons 601 are configured to interface with receiving protrusions 605 in components of the heat spreader 400, e.g., the first side component 401, the second side component 402 and the notched cap 412. For example, the fin protrusions 604 can fit within the space separating the receiving protrusions 605. The receiving protrusions 605 may be formed by machining or etching operations. The fin protrusions 604 and receiving protrusions 605 provide increased surface area for heat exchange between the piston 601 and the heat spreader 400 when compared to embodiments that mainly employ the compliant thermal connector 602 for heat exchange across the deformable joint 600. In some embodiments, a thermal oil 606 may be present at an interface of the fin protrusions 604 and the receiving protrusions 605. The thermal oil 606 can include mineral and synthetic oils. Mineral oils are refined petroleum-based hydrocarbons produced through distillation. These oils include paraffins, napthenes, and aromatic oils. In some embodiment, a compliant thermal connector 602 may be present on opposing sides of the region of the pistons 601 including the fin protrusions 604. The compliant thermal connector 602 may be bonded to the piston 601 and the heat spreader 400 using solder bonding and/or adhesives. In some embodiments, the deformable joints 600 including the compliant thermal connector 602 and the pistons 601 having fin protrusions 604 for heat exchange may be employed for heat dissipation and controlling thermo-mechanical strain effects for at least one of the stacked semiconductor device structure 200 and the processing unit 500.

FIG. 10 is a side cross-sectional view of another embodiment of an electrical device including coolant passages 414 integrated into the heat spreader 400. In some embodiments, the coolant passages 414 are also integrated into the notched cap 412 that is present on the heat spreader 400. The coolant passages 414 can be used to flow a cooling liquid, such as water or dielectric liquid through the heat spreader 400. The coolant passages 414 that are depicted in FIG. 10 may be integrated into the heat spreader 400 for any of the electrical devices described herein.

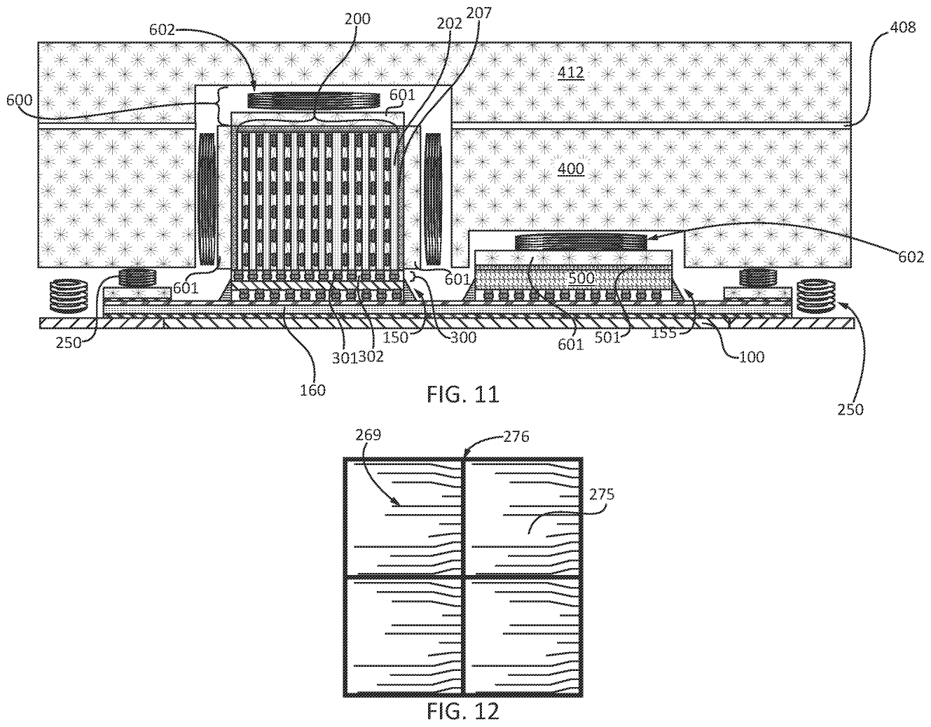

FIG. 11 is a side cross-sectional view of another embodiment of a semiconductor device structure that includes a laminate layer 160 that is integrated into the device substrate 100. The laminate layer 160 is configured to rigid in order to increase the stiffness of the device substrate 100. For example, the rigidity of the laminate layer 160 is greater than the rigidity of the device substrate 100. In some examples, the laminate layer 160 is a glass-reinforced epoxy laminate. In other examples, the laminate layer 160 includes a glass-reinforced epoxy laminate that includes pin through holes (PTH). In yet other examples, the laminate layer 160 may include an alternate core material such as glass, silicon or an organic material. The laminate layer 160 can include through glass vias (TGV), through silicon vias (TSV) or through inorganic vias (TIV) present extending through the core material. In some embodiments, the laminate layer 160 includes an additional stiffening material positioned around a perimeter of the laminate layer 160. In some embodiments, by increasing the stiffness of the device substrate 100, the laminate layer 160 to counter the thermo-mechanical stresses that can result from dimensional changes that an occur in the heat spreader 400 when subjected to changes in temperature. More specifically, in some embodiments, by increasing the stiffness of the device substrate 100, the device substrate 100 can be more resistant to warpage. The laminate layer 160 that is depicted in FIG. 11 may be integrated into the device substrate 100 for any of the electrical devices described herein.

FIG. 12 illustrates an embodiment of forming a backside redistribution layer (RDL) 269 on a semiconductor wafer. Forming the backside redistribution layer (RDL) 269 may be referred to as an initial step in a method for forming a device in which thermal cooling of the stacked semiconductor device structure 200 employs the sidewall of the stack being engaged to the device substrate 100 to provide thermal pathways to the center of the stacked semiconductor device structure 200. More particularly, in some embodiments, the metal lines of the backside redistribution layer 269 can provide thermal pathways to semiconductor devices present within the interior of the stacked semiconductor device structure 200,

FIG. 12 illustrates semiconductor devices being manufactured on a semiconductor wafer 275, in which the backside redistribution layer (RDL) 269 is a plurality of metal lines bringing electrical signal to the semiconductor devices. The metal lines of the backside redistribution layer (RDL) 269 may be formed using deposition and patterning steps. In some examples, the metal lines may also be formed using printing technology. It Is noted that FIG. 12 is a magnified view illustrating a portion of a wafer that would provide four chips. In the example depicted in FIG. 12, the portion of the semiconductor wafer 275 that is depicted is diced into four of the semiconductor chip levels 202 along the dicing lines 276.

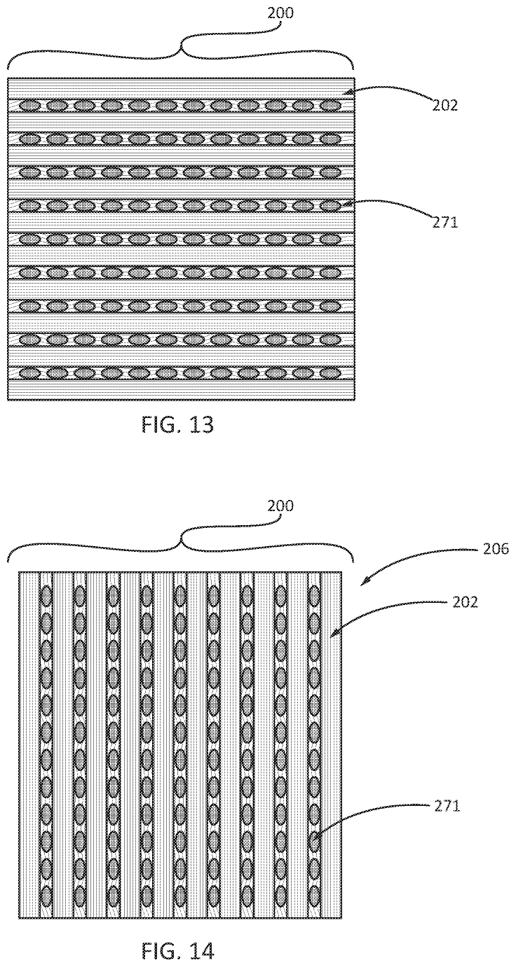

FIG. 13 is a side cross-sectional view illustrating dicing of the semiconductor wafer into semiconductor chip levels 202, and stacking the chips to provide the stacked semiconductor device structure 200. In some instances, prior to dicing the semiconductor wafer, solder connections, such as solder bumps 271 (also referred to as solder balls) may be applied to some electrical contacts of the semiconductor chip levels 202. The solder bumps 271 may be applied by screen printing, electroplating or injection molding soldering (IMS). Following application of the solder bumps 271, a dicing operation is applied. The semiconductor chip levels 202 can then be stacked and joined using hybrid bonding and/or thermal bonding to provide the stacked semiconductor device structure 200. The solder bumps 271 may provide for electrical communication between the semiconductor chip levels 202 that are adjacently stacked in the stacked semiconductor device structure 200. Any number of layers of semiconductor chip levels 202 may be present in the stacked semiconductor device structure 200. For example, the number of the semiconductor chip levels 202 may be equal to four layers or eight layers.

FIG. 14 is a side cross-sectional view illustrating rotating the stacked semiconductor device structure 200 approximately 90 degrees from its position depicted in FIG. 13. By rotating the stacked semiconductor device structure 200, a sidewall is positioned to provide the base surface for the stacked semiconductor device structure 200 that will engage the first socket 150. In some embodiments, the stacked semiconductor device structure 200 may be planarized, e.g., using chemical mechanical planarization (CMP). Any divots in the sidewall that is being processed to provide the interconnect to the first socket 150 of the device substrate 100 may be filled with a thermally conductive fill. The thermally conductive fill may have a thermal conductivity ranging from 0.4 W/mk to 1.0 W/mk.

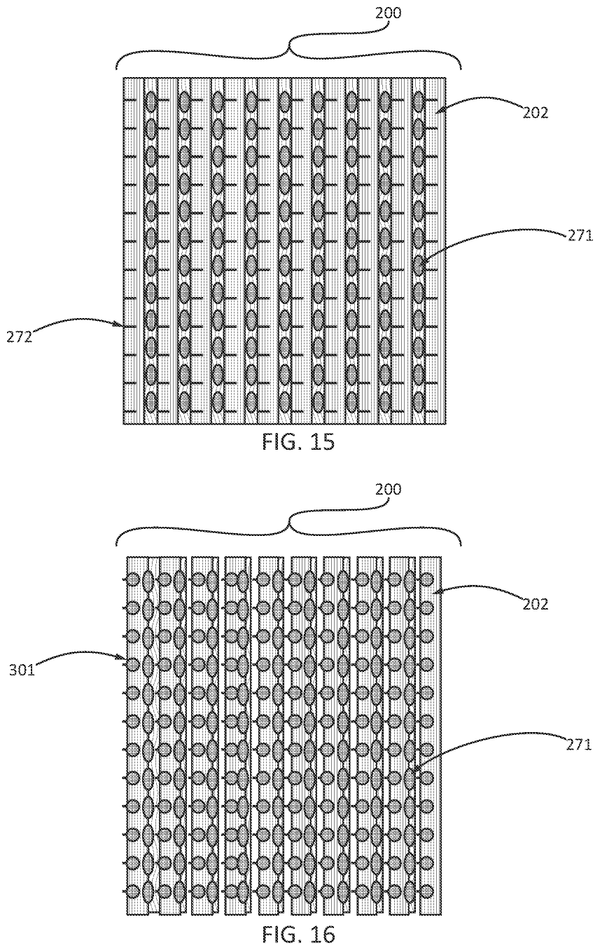

FIG. 15 bottom view depicting an embodiment of forming a sidewall redistribution layer (RDL) 272 on the planarized sidewall of the stacked semiconductor device structure 200. The sidewall redistribution layer (RDL) 272 contacts the backside redistribution layer (RDL) 269, and provides the contact points for sidewall interconnect 300 that is subsequently formed. The metal lines of the sidewall redistribution layer (RDL) 272 may be formed using deposition and patterning steps. In some examples, the metal lines may also be formed using printing technology.

FIG. 16 is a bottom view depicting an embodiment of forming the metal contacts 301 for the sidewall interconnect 300 on contact portions of the sidewall redistribution layer (RDL) 272. The metal contacts 301 may be formed using electroplating or injection molded soldering.

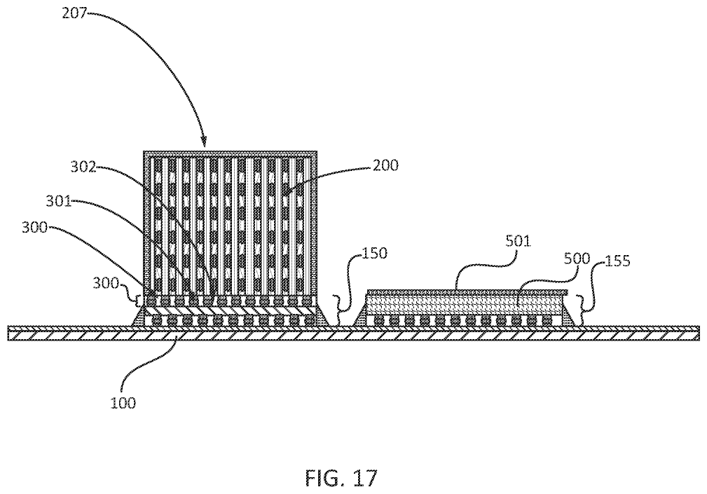

FIG. 17 is a side cross-sectional view depicting an embodiment of engaging the stacked semiconductor device structure 200 to the first socket 150 of the device substrate 100, and forming a thermal interface material (TIM) layer 207 on the stacked semiconductor device structure 200. The metal contacts 301 for the stacked semiconductor device structure 200 are first inserted into the first socket 150 of the device substrate 100. The metal contacts 301 are inserted into electrical contact with electrically conductive features of the first socket 150. The metal contacts 301 for the stacked semiconductor device structure 200 may be engaged to the metal contacts of the first socket 150 using a solder bonding or reflow process. Underfills are used to provide the dielectric fill 302 that mechanical reinforces to the metal contacts 301 that connect a chip to first socket 150. The underfill may be an epoxy, acrylic or silicone based material.

In some embodiments, the thermal interface material (TIM) layer 207 may be deposited on the stacked semiconductor device structure 200. The thermal interface material (TIM) layer 207 may be deposited using a chemical vapor deposition process. In some embodiments, the thermally conductive polymeric pad 213 can be positioned on the exterior surfaces of the stacked semiconductor device structure 200 at this stage of the process flow. However, the thermally conductive polymeric pad 213 is optional, and may be omitted.

FIG. 17 also depicts the processing unit 500 engaged to the second socket 155 of the device substrate 100. The processing unit interface layer 501 may then be formed on the processing unit 500. Similar to the stacked semiconductor device structure 200 being engaged to the first socket 150 of the device substrate 100, the processing unit 500 may be engaged to the second socket 155 of the device substrate 100 using a solder bond and underfill process.

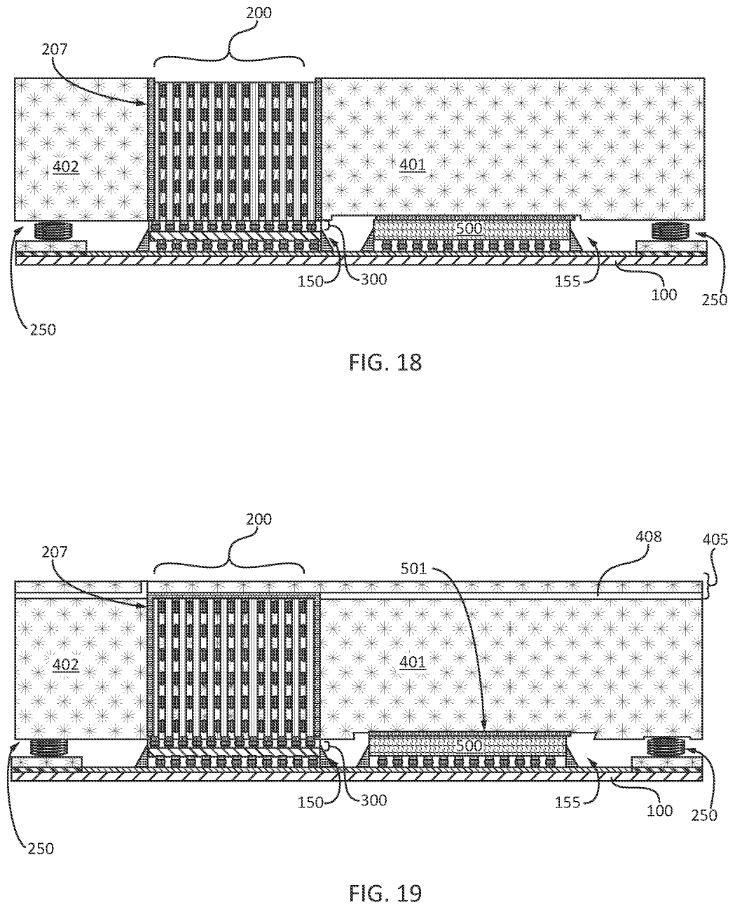

FIG. 18 is a side cross-sectional view depicting one embodiment of connecting the heat spreader 400 to the stacked semiconductor device structure 200 and the processing unit 500. In the embodiment that is depicted in FIG. 18, the heat spreader 400 is a multi-component structure. For example, FIG. 18 illustrates engagement of the first side component 401 and the second side component 402 of the heat spreader 400 to the stacked semiconductor device structure 200. Engagement of the first side component 401 and second side component 402 of the heat spreader 400 to the stacked semiconductor device structure 200 may be through a thermal interface material (TIM) layer 207. In other embodiments, adhesives may also be used. In some embodiments, the heat spreader 400 may be modified to allow for engagement of the first side component 401 and the second side component 402 to the stacked semiconductor device structure 200 through deformable joints 600 that include a piston 601 and a compliant thermal connector 602, as described above with reference to FIG. 6. The piston 601 is in direct contact with the stacked semiconductor device structure 200. The piston 601 may be engaged using bonding through the thermal interface material (TIM) layer 207 or using a thermally conductive adhesive. The compliant thermal connectors 602 may be bonded using solder bonded or thermal adhesives. In some embodiments, the piston 601 of the deformable joints 600 may include fin protrusions 604 that mesh with receiving protrusions 605 on the first side component 401 and the second side component 402 of the heat spreader 400, as depicted in FIG. 9.

FIG. 18 further illustrates connecting the heat spreader 400 to the device substrate 100. The heat spreader 400 is connected to the device substrate 100 through pillars 250 that are deformable along the dimension (Z-axis) separating the heat spreader 400 from the device substrate 100. In some embodiments, the pillars 250 are provided by thermally conductive springs. The thermally conductive springs may be connected to the seal band 105 of the device substrate 100 using solder bonding or a thermally conductive adhesive. Solder bonding or thermally conductive adhesives may also be used to connect the thermally conductive springs that can provide the pillars 250 to the first side component 401 and second side component 402 of the heat spreader 400.

FIG. 19 is a side cross-sectional view of connecting the cap layer 405 to the first side component 401 and second side component 402 of the heat spreader 400, as well as the stacked semiconductor device structure 200. The cap layer 405 may be bonded to the first side component 401 and second side component 402 of the heat spreader 400, as well as the stacked semiconductor device structure 200, using bonding through the cap thermal interface material (TIM) layer 408. In some embodiments, the cap layer 405 may be engaged to the first side component 401 and the second side component 402 of the heat spreader 400 using a thermally conductive adhesive, such as an adhesive including a metal particular filler, such as silver composition filler. In some embodiments, a notched cap 412, as used in the embodiments described with reference to FIGS. 8-11, may be substituted for the cap layer 405. When employing a notched cap 412, the stacked semiconductor device structure 200 can be engaged to the opening 411 in the notched cap through deformable joints 600 that include the piston 601 and the compliant thermal connector 602, as described above with reference to FIG. 6. The piston 601 is in direct contact with the upper surface of the stacked semiconductor device structure 200. The piston 601 may be engaged using bonding through the thermal interface material (TIM) layer 207 or using a thermally conductive adhesive. The compliant thermal connectors 602 may be bonded using solder bonded or thermal adhesives. In some embodiments, the piston 601 of the deformable joints 600 may include a plurality of fin protrusions that mesh with receiving fin protrusions in the opening 411 of the notched cap 412, as depicted in FIG. 9.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of a chiplet integration structure for thermal management (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. An electrical device comprising:
a stacked semiconductor device structure connected to a device substrate through a sidewall interconnect, wherein the sidewall interconnect is in contact with metal lines extending from a sidewall of the stacked semiconductor device structure to semiconductor devices positioned within an interior the stacked semiconductor device structure; and
a heat spreader connected to the stacked semiconductor device structure.

2. The electrical device of claim 1, wherein the heat spreader is engaged to the device substrate though pillars that deform along a direction separating the device substrate from the heat spreader.

3. The electrical device of claim 2, wherein the pillars include springs.

4. The electrical device of claim 1, wherein the metal lines and the sidewall interconnect provide thermally conductive pathways from the semiconductor devices within the stacked semiconductor device structure to the device substrate.

5. The electrical device of claim 1, wherein the heat spreader is in direct contact with faces of the stacked semiconductor device structure that are not directly connected to the device substrate.

6. The electrical device of claim 1, wherein the heat spreader is a multi-component structure including side components on each side of the stacked semiconductor device structure, and a cap layer atop the stacked semiconductor device structure and atop each of the side components.

7. The electrical device of claim 1, wherein the heat spreader includes coolant passages.

8. The electrical device of claim 1, wherein an interface between the heat spreader and the stacked semiconductor device structure includes a thermal interface material (TIM) layer.

9. The electrical device of claim 1 further comprising a laminate in contact with the device substrate, wherein the laminate has a greater rigidity than the device substrate.

10. An electrical device comprising:
a stacked semiconductor device structure connected to a device substrate through a sidewall interconnect;
a heat spreader connected to the stacked semiconductor device structure; and
pillars connecting the heat spreader to the device substrate, wherein the pillars deform along a dimension separating the heat spreader from the device substrate.

11. The electrical device of claim 10, wherein the pillars connecting the heat spreader to the device substrate include springs.

12. The electrical device of claim 10, wherein the pillars connecting the heat spreader to the device substrate comprise columns including a thermally conductive spring element in a polymeric matrix.

13. The electrical device of claim 10, wherein the sidewall interconnect is in contact with metal lines extending from an exterior sidewall of the stacked semiconductor device structure to semiconductor devices positioned within an interior the stacked semiconductor device structure.

14. The electrical device of claim 13, wherein the metal lines and the sidewall interconnect provide thermally conductive pathways from the semiconductor devices within the stacked semiconductor device structure to the device substrate.

15. An electrical device comprising:
a stacked semiconductor device structure connected to a device substrate through a sidewall interconnect for the stacked semiconductor device structure; and
a heat spreader connected to the stacked semiconductor device structure through a deformable joint.

16. The electrical device of claim 15, wherein the heat spreader is connected to the device substrate through pillars that deform along a dimension separating the heat spreader from the device substrate.

17. The electrical device of claim 15, wherein the deformable joint includes a piston that is present on the stacked semiconductor device structure and a deformable connector positioned between the piston and the heat spreader.

18. The electrical device of claim 15, wherein the deformable joint includes a piston having fin protrusions that is present on the stacked semiconductor device structure, the fin protrusions of the piston being configured to fit into receiving protrusions that are present on the heat spreader.

19. The electrical device of claim 18, wherein the deformable joint includes springs connecting the piston to the heat spreader.

20. The electrical device of claim 18, wherein a thermal conductive grease is present between the fin protrusions and the receiving protrusions.
